(19) United States
(12) Patent Application Publication
(10) Pub. No.: US 2022/0223421 A1
(43) Pub. Date: Jul. 14, 2022

(54) MANUFACTURING METHOD FOR SEMICONDUCTOR STRUCTURE, AND SEMICONDUCTOR STRUCTURE

(71) Applicant: CHANGXIN MEMORY TECHNOLOGIES, INC., Hefei City (CN)

(72) Inventors: Mengmeng YANG, Hefei (CN); Jie BAI, Hefei (CN)

(21) Appl. No.: 17/470,150

(22) Filed: Sep. 9, 2021

Related U.S. Application Data
(63) Continuation of application No. PCT/CN2021/103726, filed on Jun. 30, 2021.

(30) Foreign Application Priority Data
Jan. 14, 2021 (CN) 202110047944.4

(51) Int. Cl. H01L 21/28; H01L 27/108; H01L 29/423; H01L 29/40

(52) U.S. Cl. CPC H01L 21/28176; H01L 27/10873; H01L 29/401; H01L 29/42376; H01L 29/42364

(57) ABSTRACT

A manufacturing method for a semiconductor structure of the disclosure includes: a first stack layer is formed; a sacrificial layer is provided on the first stack layer; thermal annealing treatment is performed on the first stack layer and the sacrificial layer so that the first stack layer is formed into a second stack layer; the sacrificial layer and a work function composite layer and a first conductive layer of the second stack layer are removed, and a substrate, a second interface layer and a high-k layer of the second stack layer are retained; and a gate layer is formed on the high-k layer.

### CROSS-REFERENCE TO RELATED APPLICATIONS

This application is a continuation of International Application No. PCT/CN2021/103726, filed on Jun. 30, 2021, which claims priority to Chinese patent application No. 202110047944.4, filed on Jan. 14, 2021. The disclosures of International Application No. PCT/CN2021/103726 and Chinese patent application No. 202110047944.4 are hereby incorporated by reference in their entireties.

### TECHNICAL FIELD

The disclosure relates to the field of semiconductor manufacturing technologies, and in particular, to a manufacturing method for a semiconductor structure, and a semiconductor structure.

### BACKGROUND

A transistor is an important device in a dynamic random access memory (DRAM for short), and the performance of the transistor affects the access performance of a DRAM device.

As the size of the transistor continues to reduce, High-k and Metal Gate (HKMG) technology has become a common preparation method for a transistor device with a critical dimension less than 45 nm, which can improve the turn-on/off speed of the transistor and reduce gate leakage current, thereby optimizing the access performance of the DRAM device. The transistor structure of the HKMG includes a substrate, a silicon oxide layer, a high-k dielectric layer, a work function adjustment layer and a metal gate stacked in sequence. In the current HKMG technology of the transistor, a heat treatment process is performed in a heat treatment furnace. In high-temperature treatment, an amorphous silicon layer resulted from a furnace tube is formed on the surfaces of the high-k dielectric layer and the work function adjustment layer, and finally the metal gate is formed on the surface of the amorphous silicon resulted from the furnace tube.

However, a relatively high thermal budget in the forming process of the amorphous silicon layer resulted from the furnace tube will affect the work function adjustment process of the transistor by the work function layer, affecting the performance of the transistor, thereby affecting the access performance of the DRAM device.

### SUMMARY

To solve at least one problem mentioned in the background, the disclosure provides a manufacturing method for a semiconductor structure and a semiconductor structure, which can optimize the work function adjustment process of a semiconductor structure, thereby improving the performance of the semiconductor structure.

To achieve the above objective, in a first aspect, the disclosure provides a manufacturing method for a semiconductor structure, including: a first stack layer is formed, where the first stack layer includes a substrate, a first interface layer, a high-k layer, a first conductive layer and a work function composite layer stacked in sequence; a sacrificial layer is provided on the first stack layer; thermal annealing treatment is performed on the first stack layer and the sacrificial layer so that the first stack layer is formed into a second stack layer, where the second stack layer includes the substrate, a second interface layer, the high-k layer, the first conductive layer and the work function composite layer stacked in sequence; the sacrificial layer and the work function composite layer and the first conductive layer of the second stack layer are removed, and the substrate, the second interface layer and the high-k layer of the second stack layer are retained; and a gate layer is formed on the high-k layer.

In a second aspect, the disclosure provides a semiconductor structure, including: a substrate, the substrate including a semiconductor layer, the semiconductor layer including a source region and a drain region, and a channel region being provided between the source region and the drain region; an interface layer, the interface layer being provided on the substrate; a high-k layer, the high-k layer being provided on the interface layer, and work function diffusion particles being gathered at an interface between the high-k layer and the interface layer; and a gate layer, the gate layer being provided on the high-k layer.

The structure of the disclosure and its other invention objectives and beneficial effects will be more apparent and understandable through the description of preferred embodiments with reference to the accompanying drawings.

### BRIEF DESCRIPTION OF THE DRAWINGS

To describe the technical solutions in embodiments of the disclosure or the prior art more clearly, the accompanying drawings required for describing the embodiments or the prior art are briefly introduced below. Apparently, the accompanying drawings in the following description show some embodiments of the disclosure, and persons of ordinary skill in the art can still derive other accompanying drawings from these accompanying drawings without creative efforts.

FIG. 1 is a schematic flowchart of a manufacturing method for a semiconductor structure provided by an embodiment of the disclosure;

FIG. 2 is a schematic flowchart of forming a first stack layer according to a manufacturing method for a semiconductor structure provided by an embodiment of the disclosure;

FIG. 3 is a schematic flowchart of performing thermal annealing treatment on a first stack layer and a sacrificial layer according to a manufacturing method for a semiconductor structure provided by an embodiment of the disclosure;

FIG. 4 is a schematic structural diagram of a semiconductor structure provided by an embodiment of the disclosure;

FIG. 5 is a front view of a semiconductor structure provided by an embodiment of the disclosure;

FIG. 6 is a schematic partial structural diagram of a semiconductor structure provided by an embodiment of the disclosure;

FIG. 7 is a schematic structural diagram of diffusion of a first type of work function diffusion particles of a semiconductor structure provided by an embodiment of the disclosure;

FIG. 8 is a schematic structural diagram of a first type of work function diffusion particles of a semiconductor structure provided by an embodiment of the disclosure between a substrate and a second interface layer;

FIG. 9 is a schematic structural diagram of diffusion of a second type of work function diffusion particles of a semiconductor structure provided by an embodiment of the disclosure;

FIG. 10 is a schematic structural diagram of a second type of work function diffusion particles of a semiconductor structure provided by an embodiment of the disclosure between a substrate and a second interface layer;

FIG. 11 is a schematic structural diagram of a substrate, a second interface layer, and a high-k layer of a semiconductor structure provided by an embodiment of the disclosure; and

FIG. 12 is a schematic structural diagram of a substrate, a second interface layer, a high-k layer, and a gate layer of a semiconductor structure provided by an embodiment of the disclosure.

### DESCRIPTION OF REFERENCE NUMERALS

10: substrate; 11: source region; 12: drain region; 13: channel region; 20: first interface layer; 21: second interface layer; 30: high-k layer; 40: first conductive layer; 50: work function composite layer; 51: work function layer; 52: second conductive layer; 60: sacrificial layer; 70: gate layer; 80: additional layer; 81: side wall; 82: metal silicon compound layer; and 83: strained silicon layer.

### DETAILED DESCRIPTION

The inventor of the disclosure discovered in an actual research process that, at present, when a transistor is manufactured using HKMG technology, a heat treatment process and a heat treatment annealing process are generally completed in a heat treatment furnace. In high-temperature treatment, an amorphous silicon layer is formed on the surfaces of a high-k dielectric layer and a work function adjustment layer, and finally, a metal gate is formed. A polysilicon sacrificial layer grown through a furnace tube requires a long-term high-temperature growth process, and therefore, this process will generate a large thermal budget, resulting in a reduction in the amount of heat reserved for a work function adjustment process, as a result, in the work function adjustment process, work function diffusion particles cannot obtain enough energy to diffuse to a predetermined layer position, so that the work function adjustment process cannot be completed. Moreover, in the process of growing the polysilicon sacrificial layer in the furnace tube, the high-temperature process used will affect the performance of the TIN material in a semiconductor structure. Meanwhile, the oxygen element in the high-k layer will also diffuse into a TiN metal layer under the influence of high temperature, resulting in an increase in the resistance of TiN.

In view of the above, in the manufacturing method for a semiconductor structure and a semiconductor structure provided by embodiments of the disclosure, a first conductive layer and a sacrificial layer are formed on a first stack layer to block the penetration of external oxygen, thereby avoiding an increase in a resistance value. In addition, the first stack layer, the first conductive layer, the sacrificial layer, and a work function are removed, and a gate layer is deposited to form a complete semiconductor peripheral gate structure. In the above preparation method, the thermal budget in the forming process of the semiconductor structure is reduced, so as to ensure that there is enough heat in the work function adjustment process in a thermal annealing process to achieve the diffusion of the work function diffusion particles and diffusion to a predetermined layer structure, achieving the work function adjustment process of the semiconductor structure, thereby optimizing the performance of the semiconductor structure having the transistor.

To make the purpose, technical solutions, and advantages of the disclosure clearer, the technical solutions in the embodiments of the disclosure will be described in more detail below with reference to the accompanying drawings in the preferred embodiments of the disclosure. In the accompanying drawings, all the time the same or similar reference numerals represent the same or similar components or components having the same or similar functions. The described embodiments are a part of the embodiments of the disclosure, but not all of the embodiments. The embodiments described below with reference to the accompanying drawings are exemplary, and are intended to explain the disclosure, but cannot be understood as a limitation to the disclosure. Based on the embodiments in the disclosure, all other embodiments obtained by persons of ordinary skill in the art without creative efforts shall fall within the scope of protection of the disclosure. The embodiments of the disclosure will be described in detail below with reference to the accompanying drawings.

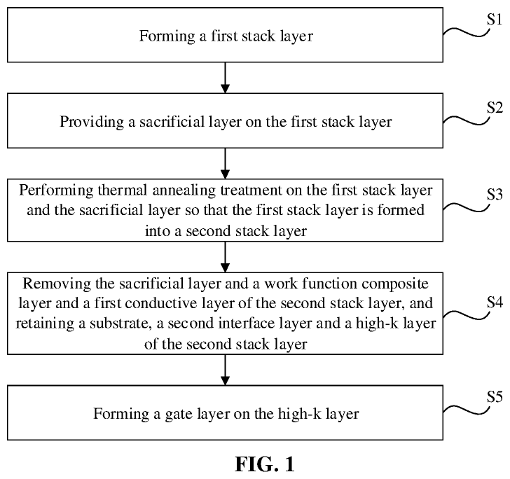

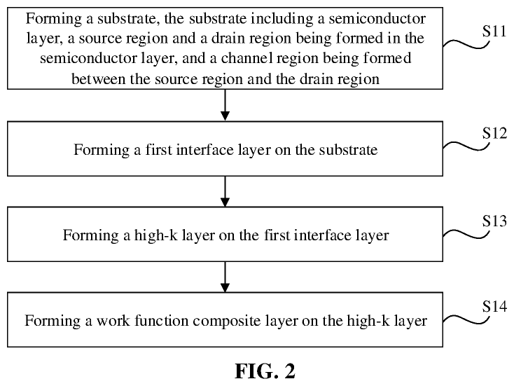

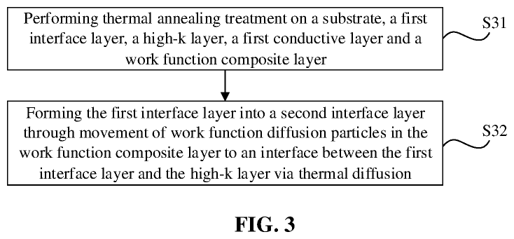

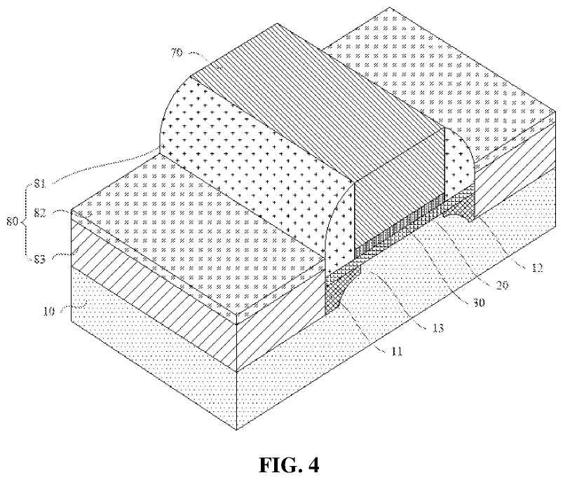

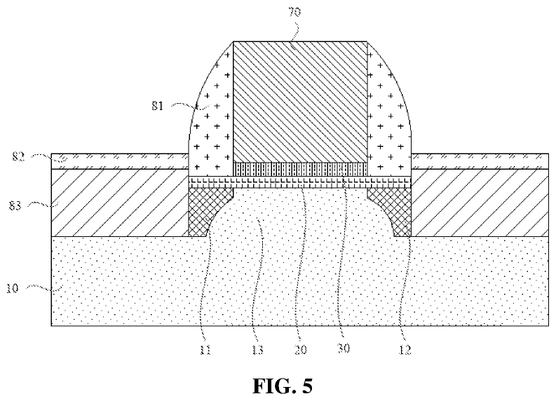

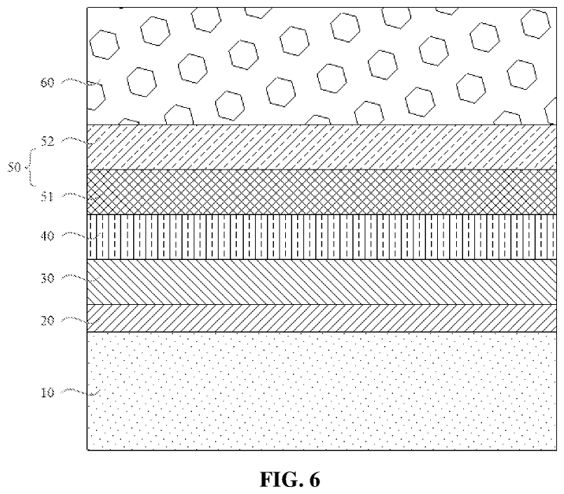

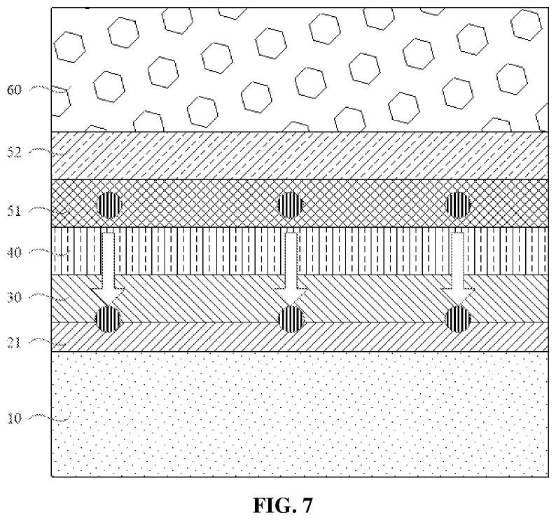

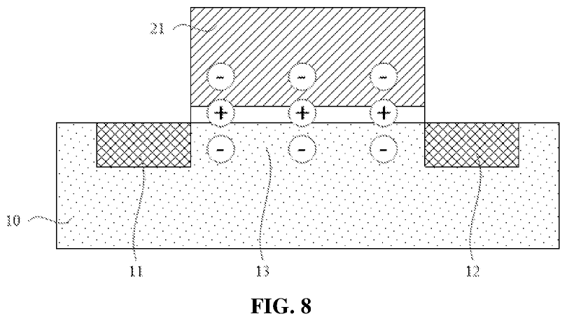

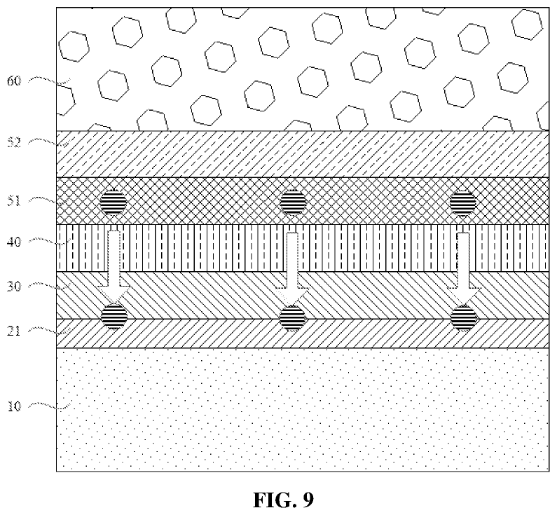

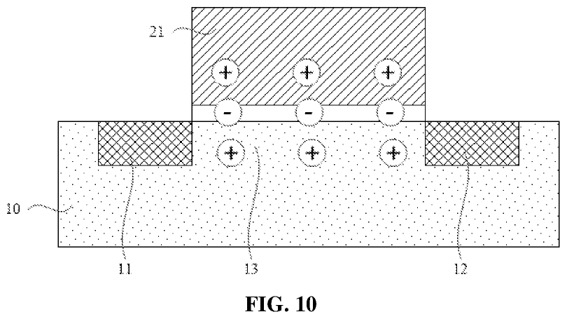

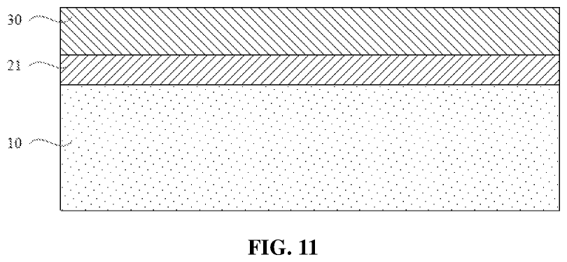

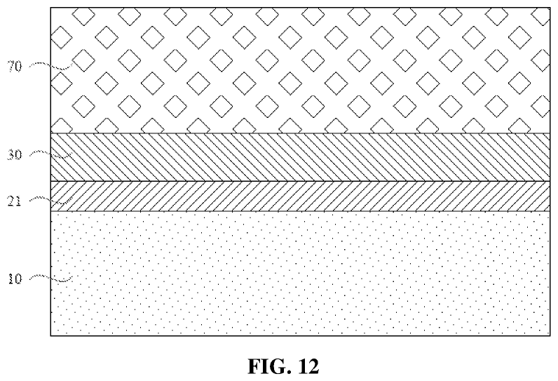

FIG. 1 is a schematic flowchart of a manufacturing method for a semiconductor structure provided by an embodiment of the disclosure. FIG. 2 is a schematic flowchart of forming a first stack layer in a manufacturing method for a semiconductor structure provided by an embodiment of the disclosure. FIG. 3 is a schematic flowchart of performing thermal annealing treatment on a first stack layer and a sacrificial layer in a manufacturing method for a semiconductor structure provided by an embodiment of the disclosure. FIG. 4 is a schematic structural diagram of a semiconductor structure provided by an embodiment of the disclosure. FIG. 5 is a front view of a semiconductor structure provided by an embodiment of the disclosure. FIG. 6 is a schematic partial structural diagram of a semiconductor structure provided by an embodiment of the disclosure. FIG. 7 is a schematic structural diagram of diffusion of a first type of work function diffusion particles of a semiconductor structure provided by an embodiment of the disclosure. FIG. 8 is a schematic structural diagram of a first type of work function diffusion particles of a semiconductor structure provided by an embodiment of the disclosure between a substrate and a second interface layer. FIG. 9 is a schematic structural diagram of diffusion of a second type of work function diffusion particles of a semiconductor structure provided by an embodiment of the disclosure. FIG. 10 is a schematic structural diagram of a second type of work function diffusion particles of a semiconductor structure provided by an embodiment of the disclosure between a substrate and a second interface layer. FIG. 11 is a schematic structural diagram of a substrate, a second interface layer, and a high-k layer of a semiconductor structure provided by an embodiment of the disclosure. FIG. 12 is a schematic structural diagram of a substrate, a second interface layer, a high-k layer, and a gate layer of a semiconductor structure provided by an embodiment of the disclosure.

Referring to FIG. 1 to FIG. 3 and also to FIG. 4 to FIG. 12, in a first aspect, an embodiment of the disclosure provides a manufacturing method for a semiconductor structure, including the following steps.

At S1, a first stack layer is formed, where the first stack layer includes a substrate 10, a first interface layer 20, a high-k layer 30, a first conductive layer 40 and a work function composite layer 50 stacked in sequence.

At S2, a sacrificial layer is provided on the first stack layer.

At S3, thermal annealing treatment is performed on the first stack layer and the sacrificial layer so that the first stack layer is formed into a second stack layer, where the second stack layer includes the substrate 10, a second interface layer 21, the high-k layer 30, the first conductive layer 40 and the work function composite layer 50.

At S4, the sacrificial layer and the work function composite layer and the first conductive layer of the second stack layer are removed, and the substrate, the second interface layer and the high-k layer of the second stack layer are retained.

At S5, a gate layer is formed on the high-k layer.

It is to be noted that the multilayer structure in the first stack layer may be stacked in sequence. Specifically, the first interface layer 20 is disposed on the substrate 10 and forms an interface with the substrate 10. The high-k layer 30 is disposed on a side of the first interface layer 20 away from the substrate 10, the first conductive layer 40 is disposed on a side of the high-k layer 30 away from the first interface layer 20, and the work function composite layer 50 is disposed on a side of the first conductive layer 40 away from the high-k layer 30.

Moreover, referring to FIG. 2, 51, i.e., forming a first stack layer specifically includes the following steps.

At S11, the substrate is formed, the substrate including a semiconductor layer, a source region and a drain region being formed in the semiconductor layer, and a channel region being formed between the source region and the drain region.

At S12, the first interface layer is formed on the substrate.

At S13, the high-k layer is formed on the first interface layer.

At S14, the work function composite layer is formed on the high-k layer.

It is to be noted that the material of the substrate 10 may be monocrystalline silicon, polycrystalline silicon, amorphous silicon, a silicon-germanium compound, or Silicon-On-Insulator (SOI for short), etc., or other materials known to persons skilled in the art, and the substrate 10 may provide a support base for the structural layers on the substrate 10. In this embodiment, the substrate 10 is a Si substrate. The substrate 10 may have a semiconductor layer, the semiconductor layer forms an active area of the substrate 10, the active area includes a source region 11 and a drain region 12, and a channel region 13 is formed between the source region 11 and the drain region 12. The first interface layer 20 is formed on the substrate 10, the first interface layer 20 is an interface layer before work function adjustment, the first interface layer 20 may be a SiO₂ layer, a Si/SiO₂ interface is formed between the substrate 10 and the first interface layer 20, and the stability of the Si/SiO₂ interface is relatively high, which can ensure the stable setting of the subsequent structural layers.

Further, the high-k layer 30 is formed on the first interface layer 20. Based on the continuous reduction of the critical dimension of the current semiconductor structure, to improve the subsequent short channel effect and quantum tunneling effect between the substrate 10 and a gate, the high-k layer 30 is used as a gate dielectric layer, and the high-k layer 30 can effectively reduce the quantum tunneling effect between the substrate 10 and the gate, thereby reducing the gate leakage current and the high power consumption caused by the gate leakage current.

As an achievable implementation mode, the material of the high-k layer 30 may include, but is not limited to: silicon dioxide, silicon carbide, aluminum oxide, tantalum pentoxide, yttrium oxide, a hafnium silicate-based oxide compound, hafnium dioxide, zirconium dioxide, strontium carbonate, and a zirconium silicate-based oxide compound. In this embodiment, the hafnium silicate-based oxide compound is taken as an example for description.

Moreover, in the first stack layer, the work function composite layer 50 is further provided on the high-k layer 30, and the work function composite layer 50 is mainly used for adjustment to increase the work function at the interface between the substrate 10 and the first interface layer 20. Further, a sacrificial layer 60 is provided on the first stack layer, and the sacrificial layer 60 and the first conductive layer 40 can work together to block the entry of external oxygen, thereby avoiding an increase in the resistance value of the layer structure caused by an oxide generated by reaction with a structural layer, such as the work function composite layer 50 or the substrate 10 in the first stack layer, after the oxygen permeates into the first stack layer.

It is to be noted that, in this embodiment, both the first conductive layer 40 and the sacrificial layer 60 are formed by physical vapor deposition, and the first conductive layer 40 and the sacrificial layer 60 are formed in different deposition chambers of a same deposition device. It is to be noted that, based on a physical vapor deposition method, a material source is gasified into gaseous atoms and molecules or partially ionized into ions under vacuum conditions, and delivered to the surface of a base through low-pressure gas to deposit a thin film on the surface of the base. Therefore, the first conductive layer 40 and the sacrificial layer 60 are prepared through the physical vapor deposition method, which can effectively control the impurity content in the environment in the forming processes of the two. Compared with a normal manufacturing process using a furnace tube, a relatively high thermal budget in the forming process can be avoided, the impurity content in the formed first conductive layer 40 or the sacrificial layer 60 is relatively high, and meanwhile, the regularity of the structure is improved. Compared with the formation of an amorphous silicon layer in heat treatment or thermal annealing treatment in the prior art, the preparation method in this embodiment reduces the thermal budget of the first conductive layer 40 and the sacrificial layer 60, and reduces the difficulty of the preparation of the two. Meanwhile, the layer structure of the two is optimized. Based on this embodiment, the thermal budget of the forming processes of the first conductive layer 40 and the sacrificial layer 60 is relatively small. In a work function adjustment process, it can be ensured that there is enough heat so that the work function particles in the work function composite layer 50 can accurately diffuse into the interface between the high-k layer 30 and the first interface layer 20, and the first interface layer 20 is formed into the second interface layer 21, instead of diffusing in the substrate 10. In this way, the work function adjustment effect of the first interface layer 20 can be ensured, and the structure of the substrate 10 can be prevented from being affected.

A thickness of the sacrificial layer 60 is in a range of 25-290 nm, and a temperature for formation of the sacrificial layer 60 is in a range of 25-400° C.

After the preparation of the first stack layer and the sacrificial layer 60 is completed, the work function adjustment process can be completed through S3. Specifically, refer to FIG. 3 and also to FIG. 7 to FIG. 10. The performing thermal annealing treatment on the first stack layer and the sacrificial layer 60 so that the first stack layer is formed into a second stack layer specifically includes the following steps.

At S31, thermal annealing treatment is performed on the substrate, the first interface layer, the high-k layer, the first conductive layer and the work function composite layer.

At S32, the first interface layer is formed into the second interface layer through movement of work function diffusion particles in the work function composite layer to an interface between the first interface layer and the high-k layer via thermal diffusion.

It is to be noted that the thermal annealing process can promote the work function diffusion particles in the work function composite layer 50 to diffuse to the interface between the first interface layer 20 and the high-k layer 30 through thermal diffusion motion, and the first interface layer 20 after work function adjustment is formed into the second interface layer 21. A thermal annealing treatment temperature is in a range of 800-1000° C., and a thermal annealing treatment time is in a range of 10 seconds to 2 hours.

Referring to FIG. 6, FIG. 7, and FIG. 9, the work function composite layer 50 includes a work function layer 51 and a second conductive layer 52 stacked in sequence, and the second conductive layer 52 is disposed on a side of the work function layer 51 away from the high-k layer 30. Through such a setting, the second conductive layer 52 can be used to reduce the mutual interference between the work function layer 51 and the high-k layer 30 as well as the first conductive layer 40, and the second conductive layer 52 can prevent the metal material in the remaining structural layers in the semiconductor structure from penetrating into the substrate 10, thereby improving the stability of the transistor structure formed in the semiconductor structure. The work function diffusion particles are in the work function layer 51.

In the work function adjustment process, as an optional implementation mode, the substrate 10 is an N-type substrate, and the source region 11, the drain region 12 and the channel region 13 are all P-type. The work function layer 51 is an aluminum oxide (AlO) layer or an aluminum (Al) layer. Referring to FIG. 7 and FIG. 8, the work function diffusion particles are Al element, which diffuse to the interface between the first interface layer 20 and the high-k layer 30, and can increase the work function of the first interface layer 20, thereby improving the ability of the first interface layer 20 to attract electrons. When the gate of the transistor in the subsequent semiconductor structure is in an on state, electrons will be enriched in the first interface layer 20, and the excess electrons in the substrate 10 will be repelled, so that the channel region 13 of the substrate 10 close to the first interface layer 20 forms a hole conduction structure, and the specific structure may be as shown in FIG. 8.

As another achievable implementation mode, the substrate 10 is a P-type substrate, and the source region 11, the drain region 12 and the channel region 13 are all N-type. The work function layer 51 is a lanthanum oxide (LaO) layer or a lanthanum (La) layer. Referring to FIG. 9 and FIG. 10, the work function diffusion particles are La element, which diffuse to the interface between the first interface layer 20 and the high-k layer 30, and can reduce the work function of the first interface layer 20, thereby improving the ability of the first interface layer 20 to attract holes. When the gate of the transistor in the subsequent semiconductor structure is in an on state, holes will be enriched in the first interface layer 20, and the excess holes in the substrate 10 will be repelled, so that the channel region 13 of the substrate 10 close to the interface forms an electron conduction structure, and the specific structure may be as shown in FIG. 10.

In actual use, the work function adjustment process is different according to the material of the work function adjustment layer, i.e., one of the above two adjustment processes, which is not limited in this embodiment. The semiconductor structure after the work function adjustment can effectively adjust the size of a threshold voltage to prevent breakdown of an oxide layer.

As an achievable implementation mode, the sacrificial layer 60 is a polysilicon layer. It is to be noted that when oxygen penetrates, the polysilicon in the polysilicon layer reacts with oxygen to produce silicon oxide, thereby further preventing subsequent oxygen penetration.

As an achievable implementation mode, the first conductive layer 40 is a TiN layer or a TaN layer. The second conductive layer 52 is a TiN layer or a TaN layer.

As an achievable implementation mode, a material of the gate layer 70 is mainly polysilicon, and tungsten can be compounded on the polysilicon. By setting a metal material, a threshold voltage drift, a polysilicon depletion effect, an excessively high gate resistance and Fermi level pinning in the gate layer can be reduced or mitigated, thereby improving the stability of the semiconductor structure.

In a second aspect, referring to FIG. 4 to FIG. 12, an embodiment of the disclosure further provides a semiconductor structure, including: a substrate 10, the substrate 10 including a semiconductor layer, the semiconductor layer including a source region 11 and a drain region 12, and a channel region 13 being provided between the source region 11 and the drain region 12;

a second interface layer 21, the second interface layer 21 being provided on the substrate 10;

a high-k layer 30, the high-k layer 30 being provided on the interface layer, work function diffusion particles being gathered at an interface between the high-k layer 30 and the second interface layer 21; and

a gate layer 70, the gate layer 70 being provided on the high-k layer 30.

It is to be noted that the semiconductor structure in this embodiment may be a DRAM device, and the substrate 10, the second interface layer 21, the high-k layer 30, and the gate layer 70 are part of layer structures in the DRAM device, and can form a transistor structure in the DRAM device. In addition, the transistor structure may further include an additional layer 80, for example, side walls 81 provided on two sides of the gate layer 70, a strained silicon layer 83 disposed on the substrate 10, and a metal silicon compound layer 82 disposed on the strained silicon layer 83. The side walls 81 can protect the structural stability of the gate layer 70. The strained silicon layer 83 is disposed on the substrate 10 and is respectively disposed on two sides of an active area, so that a channel region 13 is strained, thereby improving carrier mobility. The metal silicon compound layer 82 is disposed on the strained silicon layer 83, and can prevent the strained silicon layer 83 from reacting with the remaining layer structures on the metal silicon compound layer 82, thereby ensuring the structural stability of the strained silicon layer 83.

The second interface layer 21 is provided on the substrate 10. The high-k layer 30 is provided on the second interface layer 21. Moreover, work function diffusion particles are gathered between the second interface layer 21 and the high-k layer 30, the work function diffusion particles are used to adjust the work function between the high-k layer 30 and the second interface layer 21, facilitating the formation of a channel region 13 in an on state between the source region 11 and the drain region 12 of the substrate 10, and by adjusting the size of a threshold voltage, the turn-on/off speed of the transistor formed in the semiconductor structure is increased.

The high-k layer 30 reduces the quantum tunneling effect of a gate dielectric layer, thereby reducing the gate leakage current of the transistor formed in the semiconductor structure and the high power consumption caused thereby. Moreover, a metal material is compounded on the gate layer 70, and the gate layer 70 is stacked on the high-k layer 30 to produce a relatively small equivalent oxide thickness. Meanwhile, the gate layer 70 can reduce the threshold voltage drift of an existing polysilicon gate, a polysilicon depletion effect, an excessively high gate resistance, and the Fermi level pinning phenomenon. Therefore, the above arrangement can improve the stability of the semiconductor structure and improve the performance of the transistor formed in the semiconductor structure.

Further, the DRAM device may further include an array of a plurality of memory cells formed on the substrate 10, each memory cell including a capacitor and the transistor. The capacitor is used for storing data, and the transistor can control the access of the capacitor to the data. The gate layer 70 of the transistor is connected to a word line, the drain region 12 is connected to a bit line, and the source region 11 is connected to the capacitor. The voltage signal on the word line can control the turn-on or off of the transistor, and then the data information stored in the capacitor can be read through the bit line, or the data information is written into the capacitor through the bit line for storage to achieve the data access of the DRAM device. Therefore, when the transistor in this embodiment is applied to the DRAM device, the access performance of the DRAM device can be improved.

In the description, it is to be understood that the terms “installation”, “connected”, and “connection” is to be understood in a broad sense, unless otherwise clearly specified and limited. For example, it may be a fixed connection or an indirect connection through an intermediary, and may be internal communication between two elements or an interaction relationship between the two elements. For persons of ordinary skill in the art, the specific meanings of the above terms in the disclosure can be understood according to specific circumstances. The orientation or positional relationships indicated by the terms “on”, “under”, “front”, “back”, “vertical”, “horizontal”, “top”, “bottom”, “inside”, “outside”, etc. are based on the orientation or positional relationships shown in the drawings, and are only to facilitate the description of the disclosure and simplify the description, rather than to indicate or imply that the apparatus or element represented thereby must have a specific orientation and be constructed and operated in a specific orientation, and cannot be understood as a limitation to the disclosure. In the description of the disclosure, “a plurality of” means two or more, unless otherwise exactly specified.

The terms “first”, “second”, “third”, “fourth”, etc. (if exist) in the description and claims of the disclosure and the above drawings are used to distinguish similar objects, without having to describe a specific order or sequence. It is to be understood that the data used in this way can be interchanged under appropriate circumstances, so that the embodiments of the disclosure described herein can be implemented in an order other than those illustrated or described herein, for example. In addition, the terms “including” and “having” as well as any variations thereof are intended to cover non-exclusive inclusions. For example, processes, methods, systems, products, or devices including a series of steps or units are not necessarily limited to the steps or units clearly listed, but may include other steps or units that are not clearly listed or are inherent to these processes, methods, products, or devices.

Finally, it is to be noted that the foregoing embodiments are only used to describe the technical solutions of the disclosure, not to limit same. Although the disclosure is described in detail with reference to the foregoing embodiments, persons of ordinary skill in the art should understand that they can still modify the technical solutions described in the foregoing embodiments, or equivalently replace some or all of the technical features; and these modifications or replacements do not cause the essence of the corresponding technical solutions to deviate from the scope of the technical solutions of the embodiments of the disclosure.

1. A manufacturing method for a semiconductor structure, comprising:
forming a first stack layer, wherein the first stack layer comprises a substrate, a first interface layer, a high-k layer, a first conductive layer and a work function composite layer stacked in sequence;
providing a sacrificial layer on the first stack layer;
performing thermal annealing treatment on the first stack layer and the sacrificial layer so that the first stack layer is formed into a second stack layer, wherein the second stack layer comprises the substrate, a second interface layer, the high-k layer, the first conductive layer and the work function composite layer stacked in sequence;
removing the sacrificial layer and the work function composite layer and the first conductive layer of the second stack layer, and retaining the substrate, the second interface layer and the high-k layer of the second stack layer; and
forming a gate layer on the high-k layer.

2. The manufacturing method for a semiconductor structure of claim 1, wherein forming the first stack layer specifically comprises:
forming the substrate, the substrate comprising a semiconductor layer, a source region and a drain region being formed in the semiconductor layer, and a channel region being formed between the source region and the drain region;
forming the first interface layer on the substrate;
forming the high-k layer on the first interface layer; and
forming the work function composite layer on the high-k layer.

3. The manufacturing method for a semiconductor structure of claim 1, wherein both the first conductive layer and the sacrificial layer are formed by physical vapor deposition, and the first conductive layer and the sacrificial layer are formed in different deposition chambers of a same deposition device.

4. The manufacturing method for a semiconductor structure of claim 3, wherein a thickness of the sacrificial layer is in a range of 25-290 nm, and a temperature for formation of the sacrificial layer is in a range of 25-400° C.

5. The manufacturing method for a semiconductor structure of claim 2, wherein performing thermal annealing treatment on the first stack layer and the sacrificial layer so that the first stack layer is formed into the second stack layer specifically comprises:
performing thermal annealing treatment on the substrate, the first interface layer, the high-k layer, the first conductive layer and the work function composite layer; and
forming the first interface layer into the second interface layer through movement of work function diffusion particles in the work function composite layer to an interface between the first interface layer and the high-k layer via thermal diffusion.

6. The manufacturing method for a semiconductor structure of claim 5, wherein during performing thermal annealing treatment on the substrate, the first interface layer, the high-k layer, the first conductive layer and the work function composite layer, a thermal annealing treatment temperature is in a range of 800-1000° C., and a thermal annealing treatment time is in a range of 10 seconds to 2 hours.

7. The manufacturing method for a semiconductor structure of claim 1, wherein the sacrificial layer is a polysilicon layer.

8. The manufacturing method for a semiconductor structure of claim 5, wherein the work function composite layer comprises a work function layer and a second conductive layer stacked in sequence, and the second conductive layer is disposed on a side of the work function layer away from the high-k layer; and
the work function diffusion particles are in the work function layer.

9. The manufacturing method for a semiconductor structure of claim 2, wherein the substrate is an N-type substrate, and the source region, the drain region and the channel region are all P-type; and
a work function layer in the work function composite layer is an AlO layer or an Al layer, and work function diffusion particles are Al element.

10. The manufacturing method for a semiconductor structure of claim 2, wherein the substrate is a P-type substrate, and the source region, the drain region and the channel region are all N-type; and
a work function layer in the work function composite layer is a LaO layer or a La layer, and work function diffusion particles are La element.

11. The manufacturing method for a semiconductor structure of claim 8, wherein the first conductive layer is a TiN layer or a TaN layer; and/or
the second conductive layer is a TiN layer or a TaN layer.

12. The manufacturing method for a semiconductor structure of claim 1, wherein the substrate is a Si layer, the first interface layer is a SiO₂ layer, and a Si/SiO₂ interface is formed between the substrate and the first interface layer.

13. The manufacturing method for a semiconductor structure of claim 1, wherein a material of the high-k layer is silicon dioxide, silicon carbide, aluminum oxide, tantalum pentoxide, yttrium oxide, a hafnium silicate-based oxide compound, hafnium dioxide, zirconium dioxide, strontium carbonate, and a zirconium silicate-based oxide compound.

14. The manufacturing method for a semiconductor structure of claim 1, wherein a material of the gate layer is polysilicon.

15. A semiconductor structure, comprising:
a substrate, the substrate comprising a semiconductor layer, the semiconductor layer comprising a source region and a drain region, and a channel region being provided between the source region and the drain region;
an interface layer, the interface layer being provided on the substrate;
a high-k layer, the high-k layer being provided on the interface layer, and work function diffusion particles being gathered at an interface between the high-k layer and the interface layer; and
a gate layer, the gate layer being provided on the high-k layer.
